(19) United States
(12) Patent Application Publication
(10) Pub. No.: US 2026/0173604 A1
(43) Pub. Date: Jun. 18, 2026

(54) LIGHT EMITTING ELEMENT TRANSFER APPARATUS, AND METHOD OF DRIVING LIGHT EMITTING ELEMENT TRANSFER APPARATUS

(71) Applicant: LG Display Co., Ltd., Seoul (KR)

(72) Inventors: DoYoung KWAK, Paju-si (KR); Youngsuk HWANG, Paju-si (KR); Bongseok CHOI, Paju-si (KR)

(73) Assignee: LG Display Co., Ltd., Seoul (KR)

(21) Appl. No.: 19/246,406

(22) Filed: Jun. 23, 2025

(30) Foreign Application Priority Data
Dec. 18, 2024 (KR) 10-2024-0189749

(51) Int. Cl. H10H 29/03; G09G 3/32; H10W 90/00

(52) U.S. Cl. CPC H10H 29/03; G09G 3/32; H10W 90/00

(57) ABSTRACT

A light emitting element transfer apparatus and a method of driving a light emitting element transfer apparatus are discussed. The light emitting element transfer apparatus can include a plurality of injection parts into which a plurality of light emitting elements are respectively injected, a plurality of stack parts corresponding respectively to the plurality of injection parts and allowing the plurality of light emitting elements respectively injected into the plurality of injection parts to be stacked, and a plurality of output parts corresponding respectively to the plurality of stack parts and outputting sequentially the plurality of light emitting elements stacked in the plurality of stack parts.

### CROSS-REFERENCE TO RELATED APPLICATION

This application claims priority to Korean Patent Application No. 10-2024-0189749, filed on December 18, 2024 in the Korean Intellectual Property Office, the entire contents of which is hereby expressly incorporated by reference into the present application.

### BACKGROUND

### Field

The present disclosure relates to a light emitting element transfer apparatus and a method of driving the light emitting element transfer apparatus.

### Discussion of the Related Art

In today's information society, display devices for presenting images or visual information to users are increasingly important. The various needs for display devices have caused display technology to be rapidly developed, and indeed, various types of display devices, such as a liquid crystal display (LCD) device, an organic light emitting display (OLED) device, an inorganic light emitting display (iLED) device, a micro light emitting display (micro LED) device, a mini light emitting displays (mini LED) device, a quantum dot light emitting display (QLED) device, and the like, have been developed and widely used.

Display devices can include a plurality of light emitting elements. The plurality of light emitting elements can be transferred onto a substrate. The plurality of light emitting elements can be transferred onto the substrate by various techniques.

### SUMMARY OF THE DISCLOSURE

One or more aspects of the present disclosure can provide a light emitting element transfer apparatus that includes an injection part, a stack part, and an output part and is capable of aligning light emitting elements, and a method of driving the light emitting element transfer apparatus.

One or more aspects of the present disclosure can provide a light emitting element transfer apparatus that includes an injection part, a stack part, and an output part and is capable of stacking up light emitting elements, and a method of driving the light emitting element transfer apparatus.

One or more aspects of the present disclosure can provide a light emitting element transfer apparatus that includes an injection part, a stack part, and an output part and is capable of transferring light emitting elements, and a method of driving the light emitting element transfer apparatus.

One or more aspects of the present disclosure can provide a light emitting element transfer apparatus that includes an injection part, a stack part, and an output part and is capable of optimizing processes, and a method of driving the light emitting element transfer apparatus.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a light emitting element transfer apparatus can include a plurality of injection parts into which a plurality of light emitting elements are respectively injected, a plurality of stack parts corresponding respectively to the plurality of injection parts and allowing the plurality of light emitting elements respectively injected into the plurality of injection parts to be stacked, and a plurality of output parts corresponding respectively to the plurality of stack parts and outputting sequentially the plurality of light emitting elements stacked in the plurality of stack parts.

According to one or more example embodiments of the present disclosure, a method of driving a light emitting element transfer apparatus can include a light emitting element injection step of forming a first electric field by an element injection part to hold a first light emitting element among a plurality of light emitting elements in the element injection part, a light emitting element stacking step of forming a second electric field by an stack part located under the element injection part and removing the first electric field by the element injection part such that the first light emitting element moves into the stack part and is held therein, a first transfer preparation step of forming a third electric field by an output part located under the element injection part and removing the second electric field by the stack part such that the first light emitting element moves into the output part and is held therein, and a transfer step of removing the third electric field by the output part such that the first light emitting element is transferred onto a substrate.

According to one or more aspects of the present disclosure, a light emitting element transfer apparatus including an injection part, a stack part, and an output part and a method of driving the light emitting element transfer apparatus can be capable of aligning light emitting elements.

According to one or more aspects of the present disclosure, a light emitting element transfer apparatus including an injection part, a stack part, and an output part and a method of driving the light emitting element transfer apparatus can be capable of stacking up light emitting elements.

According to one or more aspects of the present disclosure, a light emitting element transfer apparatus including an injection part, a stack part, and an output part and a method of driving the light emitting element transfer apparatus can be capable of transferring light emitting elements.

According to one or more aspects of the present disclosure, a light emitting element transfer apparatus including an injection part, a stack part, and an output part and a method of driving the light emitting element transfer apparatus can be capable of optimizing processes.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an example system configuration of a display device according to aspects of the present disclosure.

FIG. 2 illustrates an example subpixel according to aspects of the present disclosure.

FIGS. 3, 4, and 5 illustrate an example light emitting element transfer apparatus configured to transfer light emitting elements according to aspects of the present disclosure.

FIGS. 6 to 13 are example cross-sectional views taken along line A-B in FIG. 5.

FIGS. 14 and 15 illustrate example transferring of light emitting elements onto a substrate in the light emitting element transfer apparatus according to aspects of the present disclosure.

FIG. 16 is a flowchart of a method of driving a light emitting element transfer apparatus according to aspects of the present disclosure.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. Where the terms “comprise,” “have,” “include,” “contain,” “constitute,” “compose, “make up of,” “formed of,” and the like are used, one or more other elements can be added unless the term, such as “only,” is used. An element described in the singular form is intended to include a plurality of elements, and vice versa, unless the context clearly indicates otherwise.

Although the terms “first,” “second,” A, B, (a), (b), and the like can be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element can be included in at least one of two or more elements that "are connected or coupled to", “contact or overlap”, etc. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Hereinafter, various example embodiments of the present disclosure will be described in detail with reference to the accompanying drawings. In addition, for convenience of description, a scale in which each of elements is illustrated in the accompanying drawings can differ from an actual scale. Thus, the illustrated elements are not limited to the specific scale in which they are illustrated in the drawings.

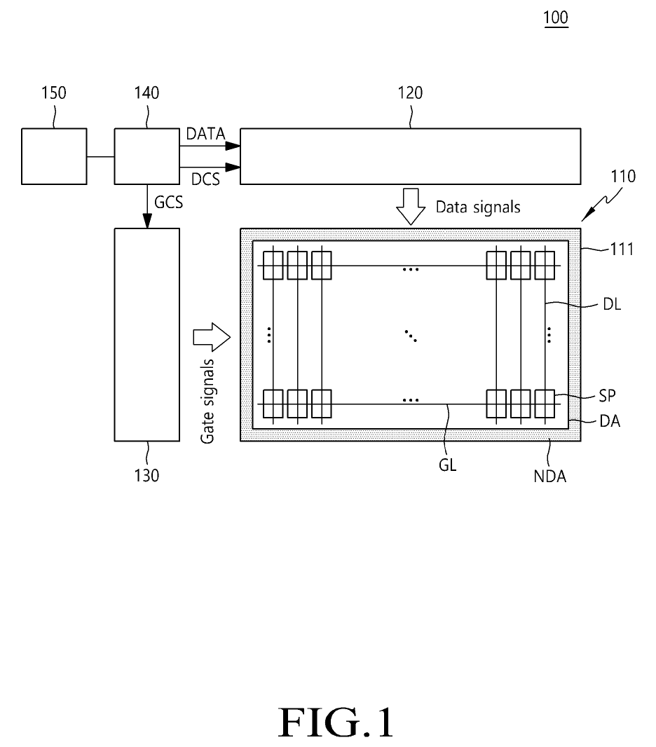

FIG. 1 illustrates an example system configuration of a display device 100 according to aspects of the present disclosure.

Referring to FIG. 1, in one or more example embodiments, the display device 100 can include a display panel 110 and at least one display driving circuit, as elements for display images. The at least one display driving circuit can be one or more circuits for driving the display panel 110, and include a data driving circuit 120, a gate driving circuit 130, a display controller 140, and other circuit components.

The display panel 110 can include a substrate 111 and a plurality of subpixels SP disposed on the substrate 111.

The substrate 111 of the display panel 110 can include a display area DA allowing an image to be displayed and a non-display area NDA located outside of the display area DA.

A plurality of subpixels SP for displaying an image can be disposed in the display area DA, and the non-display area NDA can include a pad area located in a first direction from the display area DA.

In one or more aspects, the non-display area NDA of the display panel 110 can have a very small area compared to the display area DA. Herein, the non-display area NDA can be also referred to as a non-active area, a bezel, or a bezel area.

Several types of signal lines for driving a plurality of subpixels SP can be disposed on the substrate 111 of the display panel 110.

In one or more aspects, the display device 100 can be a liquid crystal display device or the like, or a self-emission display device in which light is emitted from the display panel 110 itself. In an example where the display device 100 is the self-emission display device, each of the plurality of subpixels SP can include a light emitting element.

For example, the display device 100 can be an organic light emitting display device implemented with organic light emitting diodes (OLED) as light emitting elements. In another example, the display device 100 can be an inorganic light emitting display device implemented with inorganic material-based light emitting diodes as light emitting elements. In further another example, the display device 100 can be a quantum dot display device implemented with quantum dots, which are self-emission semiconductor crystals, as light emitting elements.

The structure of each of the plurality of subpixels SP can depend on types of display device 100. For example, in an example where the display device 100 is a self-emission display device including self-emission subpixels SP, each subpixel SP can include a self-emission light emitting element, one or more transistors, and one or more capacitors.

The several types of signal lines can include, for example, a plurality of data lines DL for carrying data signals (which can be referred to as data voltages or image signals), a plurality of gate lines GL for carrying gate signals (which can be referred to as scan signals), and the like.

The data driving circuit 120 can be a circuit for driving a plurality of data lines DL and can output data signals to the plurality of data lines DL.

The data driving circuit 120 can receive image data DATA in digital form from the display controller 140, convert the received image data DATA into data signals in analog form, and output converted data signals to the plurality of data lines DL.

The data driving circuit 120 can be located in, and/or electrically connected to, but not limited to, only one side or edge (e.g., an upper portion or a lower portion) of the display panel 110. In one or more aspects, the data driving circuit 120 can be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 can be connected to outside, or an edge, of the display area DA of the display panel 110, or be disposed in the display area DA of the display panel 110.

The gate driving circuit 130 can be a circuit for driving a plurality of gate lines GL and can output gate signals to the plurality of gate lines GL.

The gate driving circuit 130 can receive various types of gate driving control signals GCS, and further receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

The display controller 140 can be a device for controlling the data driving circuit 120 and the gate driving circuit 130, and can control driving timing for the plurality of data lines DL and driving timing for the plurality of gate lines GL.

The display controller 140 can supply a data driving control signal DCS to the data driving circuit 120 to control the data driving circuit 120, and supply a gate driving control signal GCS to the gate driving circuit 130 to control the gate driving circuit 130.

The display controller 140 can receive image data input from a host system 150 and supply image data DATA readable by the data driving circuit 120 based on the input image data to the data driving circuit 120.

The display controller 140 can be implemented in a separate component from the data driving circuit 120, or incorporated in the data driving circuit 120 and thus implemented in an integrated circuit.

The display controller 140 can be a timing controller used in the typical display technology or a controller or a control device capable of performing other control functions in addition to the function of the typical timing controller. In one or more embodiments, the display controller 140 can be a controller or a control device different from the timing controller, or a circuitry or a component included in the controller or the control device.

The display controller 140 can be mounted on a printed circuit board, a flexible printed circuit, and/or the like and be electrically connected to the gate driving circuit 130 and the data driving circuit 120 through the printed circuit board, flexible printed circuit, and/or the like.

In one or more aspects, to provide a touch sensing function, as well as an image display function, the display device 100 can include a touch sensor, and a touch sensing circuit configured to sense the touch sensor and detect the presence or absence of a touch by an object such as a finger, a pen, or the like, or the location of the touch.

The touch sensing circuit can include a touch driving circuit configured to drive and sense the touch sensor and generate and output touch sensing data, and a touch controller capable of detecting the presence or absence of a touch or the location of the touch using the touch sensing data.

The touch sensor can include a plurality of touch electrodes. The touch sensor can further include a plurality of touch lines to electrically connect the plurality of touch electrodes to the touch driving circuit.

The touch driving circuit can supply a touch driving signal to at least one of a plurality of touch electrodes and generate touch sensing data by sensing at least one of the plurality of touch electrodes.

In one or more aspects, the touch driving circuit and touch controller included in the touch sensing circuit can be implemented in separate devices or in a single device. In one or more aspects, the touch driving circuit and the data driving circuit can be implemented in separate devices or in a single device.

The display device 100 can further include a power supply circuit for supplying various types of power to the display driving circuit and/or the touch sensing circuit.

In one or more embodiments, the display device 100 can further include an electronic device such as a camera (e.g., an image sensor), a sensor capable of detecting an object, and the like. For example, the sensor can be a sensor capable of detecting an object or a human body by receiving light such as infrared light, ultrasonic light, ultraviolet light or the like.

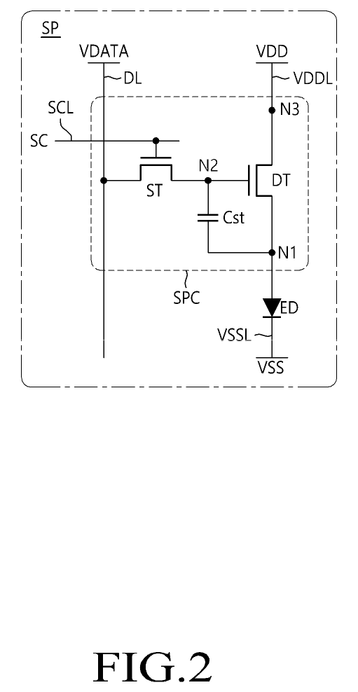

FIG. 2 illustrates an example subpixel according to aspects of the present disclosure.

Referring to FIG. 2, in one or more example embodiments, each of a plurality of subpixels SP can include a light emitting element ED and a subpixel circuit SPC for driving the light emitting element ED.

The subpixel circuit SPC can include a plurality of pixel driving transistors and at least one capacitor for driving the light emitting element ED. The subpixel circuit SPC can drive the light emitting element ED by supplying a driving current to the light emitting element ED at a predefined timing. The light emitting element ED can emit light by being driven by the driving current.

The plurality of pixel driving transistors can include a driving transistor DT for driving the light emitting element ED and a scan transistor ST configured to be turned on or off according to a scan signal SC.

The driving transistor DT can supply a driving current to the light emitting element ED.

The scan transistor ST can be configured to control an electrical state of a corresponding node in the subpixel circuit SPC or to control the state or operation of the driving transistor DT.

The at least one capacitor can include a storage capacitor Cst configured to maintain a constant voltage during a display frame or a certain period of the display frame.

To drive one or more subpixels SP, at least one data signal VDATA, which is an image signal, and at least one scan signal SC, which is a gate signal, can be applied to the one or more subpixels SP. Further, a common pixel driving voltage including a first common driving voltage VDD and a second common driving voltage VSS can be applied to the one or more subpixels SP.

In one or more embodiments, the light emitting element ED can be an organic light emitting diode, an inorganic material-based light emitting diode, a quantum dot light emitting diode, a micro light emitting diode, a mini light emitting diode, or the like. For example, in an example where the light emitting element ED is an organic light emitting diode (OLED), a light emitting element intermediate layer EL of the light emitting element ED can include an organic material.

The driving transistor DT can be a transistor configured to supply a driving current to the light emitting element ED. The driving transistor DT can be connected between a first common driving voltage line VDDL and the light emitting element ED.

The driving transistor DT can include a first node N1 electrically connected with the light emitting element ED, a second node N2 to which a data signal VDATA is applied, and a third node N3 to which a driving voltage VDD from a driving voltage line DVL (e.g., the first common driving voltage line VDDL) is applied.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes, respectively. However, embodiments of the present disclosure are not limited thereto.

The scan transistor ST included in the subpixel circuit SPC illustrated in FIG. 2 can be a switching transistor for allowing a data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

In one or more aspects, the storage capacitor Cst, which can be present between the first node N1 and the second node N2 of the driving transistor DT, can be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like).

Each of the driving transistor DT and the scan transistor ST can be an n-type transistor or a p-type transistor.

The display panel 110 can have a top emission structure or a bottom emission structure.

In an example where the display panel 110 has the top emission structure, at least a portion of the subpixel circuit SPC can overlap with at least a portion of the light emitting element ED in the vertical direction. In an example where the display panel 110 has the bottom emission structure, the subpixel circuit SPC may not overlap the light emitting element ED in the vertical direction.

The subpixel circuit SPC can include two transistors (2T: DT and ST) and one capacitor (1C: Cst) (which can be referred to as a “2T1C structure”), and in one or more aspects, can further include one or more transistors, or further include one or more capacitors.

For example, the subpixel circuit SPC can have an 8T1C structure including 8 transistors and 1 capacitor. In another example, the subpixel circuit SPC can have an 6T2C structure including 6 transistors and 2 capacitor. In further another example, the subpixel circuit SPC can have an 7T1C structure including 7 transistors and 1 capacitor.

The types and number of gate signals supplied to a subpixel SP, and/or the types and number of gate lines connected to the subpixel SP can vary depending on a structure of a corresponding subpixel circuit SPC.

Further, the types and number of common pixel driving voltages supplied to a subpixel SP can vary depending on a structure of a corresponding subpixel circuit SPC.

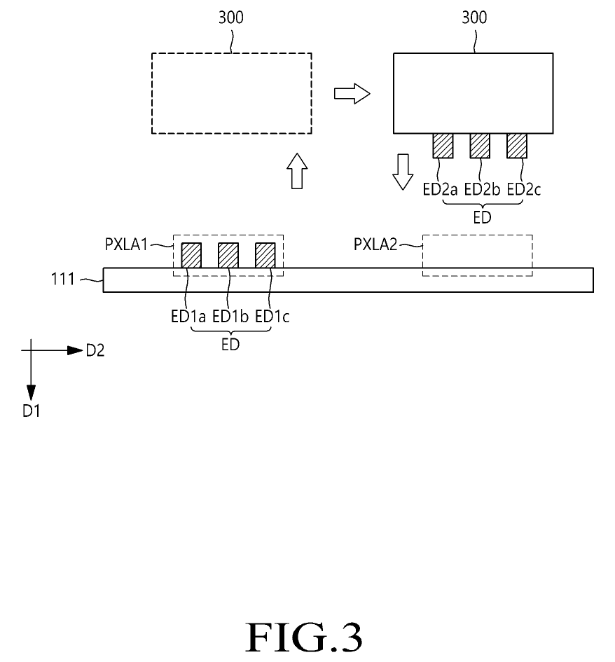

FIGS. 3, 4, and 5 illustrate an example light emitting element transfer apparatus 300 configured to transfer light emitting elements ED according to aspects of the present disclosure.

In one or more example embodiments, FIG. 3 schematically illustrates a light emitting element transfer apparatus 300. The light emitting element transfer apparatus 300 can transfer light emitting elements ED onto a substrate 111. Herein, transferring the light emitting elements ED can mean arranging the light emitting elements ED on the substrate 111.

Referring to FIG. 3, the substrate 111 can include a first pixel area PXLA1 and a second pixel area PXLA2. The first pixel area PXLA1 and the second pixel area PXLA2 can be areas where a plurality of light emitting elements ED are arranged.

The example of FIG. 3 illustrates that first light emitting elements (ED1a, ED1b, and ED1c) are arranged in the first pixel area PXLA1. The first light emitting elements (ED1a, ED1b, and ED1c) are light emitting elements ED transferred by the light emitting element transfer apparatus 300. For example, after the light emitting element transfer apparatus 300 is located on the first pixel area PXLA1, the light emitting element transfer apparatus 300 can move close to the substrate 111 and transfer the light emitting elements ED in the first pixel area PXLA1.

After the first light emitting elements (ED1a, ED1b, and ED1c) are transferred, the light emitting element transfer apparatus 300 can move away from the substrate 111. For example, the light emitting element transfer apparatus 300 can be spaced apart from the substrate 111. Thereafter, the light emitting element transfer apparatus 300 can move along a second direction D2 from the first pixel area PXLA1 to the second pixel area PXLA2.

The light emitting element transfer apparatus 300 can be spaced apart from the substrate 111 and be located on the second pixel area PXLA2. In this situation, second light emitting elements (ED2a, ED2b, and ED2c) can be held in a lower portion of the light emitting element transfer apparatus 300.

As the light emitting element transfer apparatus 300 moves close to the substrate 111 in a first direction D1, the second light emitting elements (ED2a, ED2b, and ED2c) can be transferred in the second pixel area PXLA2. A plurality of light emitting elements ED can be stored or stacked inside the light emitting element transfer apparatus 300. This will be described below.

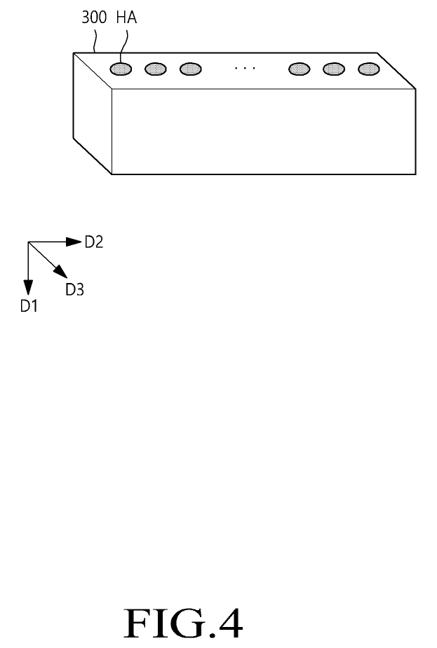

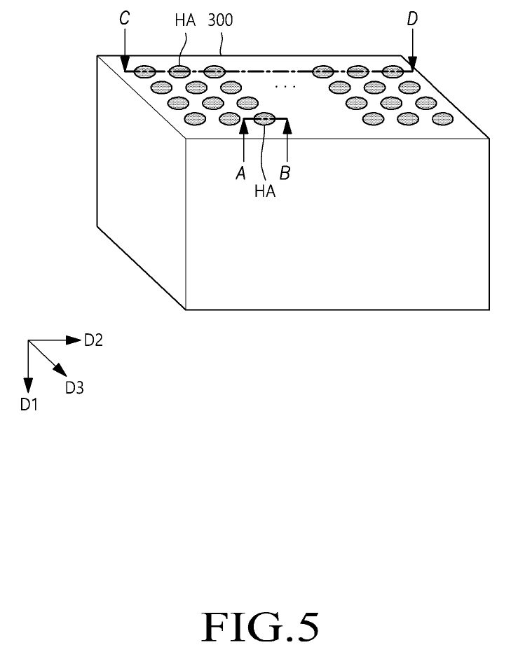

Referring to FIGS. 4 and 5, the light emitting element transfer apparatus 300 can include a plurality of hole areas HA. Referring to FIG. 4, a plurality of hole areas HA can be arranged in a row. Referring to FIG. 5, a plurality of hole areas HA can be arranged in a matrix form. A plurality of light emitting elements ED, each of which can be the light emitting element ED illustrated in FIG. 2, can be stacked inside of the plurality of hole areas HA.

The plurality of hole areas HA can have a circular shape. However, aspects of the present disclosure are not limited thereto. For example, the plurality of hole areas HA can have various shapes such as rectangles, squares, or the like.

The plurality of hole areas HA can be areas where light emitting elements ED are stacked or stored, and areas where locations of the light emitting elements ED are controlled. The light emitting element transfer apparatus 300 can control the locations of the light emitting elements ED by forming or removing electric field in the plurality of hole areas HA. The light emitting element transfer apparatus 300 can transfer the light emitting elements ED onto the substrate 111 by controlling the locations of the light emitting elements ED.

Referring to FIG. 4, the light emitting element transfer apparatus 300 can transfer a plurality of light emitting elements ED in a row. Referring to FIG. 5, the light emitting element transfer apparatus 300 can transfer a plurality of light emitting elements ED to multiple locations simultaneously. The structures of the light emitting element transfer apparatuses 300 illustrated in FIGS. 4 and 5 are only examples, and the plurality of hole areas HA located in the light emitting element transfer apparatuses 300 can be designed in various forms or patterns. Hereinafter, for convenience of explanation, the structure of the light emitting element transfer apparatus 300 will be described based on the light emitting element transfer apparatuses 300 illustrated in FIG. 5.

FIG. 5 shows area A-B and area C-D. Hereinafter, a cross-sectional view of area A-B will be described.

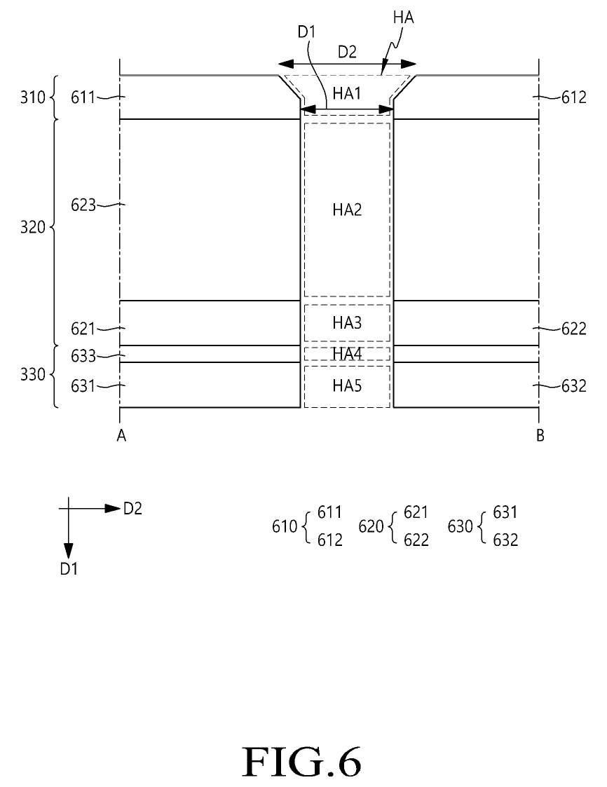

FIGS. 6 to 13 are example cross-sectional views taken along line A-B in FIG. 5.

Referring to FIG. 6, the light emitting element transfer apparatuses 300 can include an injection part 310, a stack part 320, and an output part 330. The stack part 320 can include a light emitting element stack section 623, and a stack control section 620. The output part 330 can include an insulation section 633, and a transfer output section 630.

The light emitting element transfer apparatus 300 can include an injection part 310, a light emitting element stack section 623, a stack control section 620, an insulation section 633, and a transfer output section 630. When viewed based on the cross-sectional view taken along line A-B, hole areas HA can be included inside of the injection part 310, the light emitting element stack section 623, the stack control section 620, the insulation section 633, and the transfer output section 630, respectively.

The transfer output section 630 can be located at a lowest portion of the light emitting element transfer apparatus 300. The transfer output section 630 can include a transfer positive output section 631 and a transfer negative output section 632. A fifth hole area HA5 can be located between the transfer positive output section 631 and the transfer negative output section 632.

The transfer positive output section 631 can be in a positive voltage state. The transfer negative output section 632 can be in a negative voltage state. Therefore, an electric field can be formed between the transfer positive output section 631 and the transfer negative output section 632. Electric force lines of the electric field can be directed from the transfer positive output section 631 to the transfer negative output section 632.

The transfer output section 630 can form an electric field in the fifth hole area HA5. For example, the transfer positive output section 631 can be an electrode to which a positive voltage is applied. The transfer negative output section 632 can be an electrode to which a negative voltage is applied. When a positive voltage is supplied to the transfer positive output section 631 and a negative voltage is supplied to the transfer negative output section 632, an electric field can be formed between the transfer positive output section 631 and the transfer negative output section 632.

The transfer output section 630 can form an electric field in the fifth hole area HA5. For example, the transfer positive output section 631 can be a silicon layer doped negatively. The transfer positive output section 631 can be silicon to which phosphorus, arsenic, and/or the like corresponding to group 5 are added. The transfer negative output section 632 can be a silicon layer doped positively. The transfer negative output section 632 can be silicon to which boron, aluminum, and/or the like corresponding to group 3 are added. When a positive voltage is supplied to the transfer positive output section 631 and a negative voltage is supplied to the transfer negative output section 632, an electric field can be formed between the transfer positive output section 631 and the transfer negative output section 632.

The insulation section 633 can be placed on the transfer output part 630. The insulation section 633 can include an organic material or an inorganic material. The insulation section 633 can electrically insulate the transfer output section 630 and the stack control section 620. When viewed based on the cross-sectional view illustrated in FIG. 6, a fourth hole area HA4 can be located between a left portion of the insulation section 633 and a right portion of the insulation section 633.

The stack control section 620 can be disposed on the insulation section 633. The stack control section 620 can include a stack positive control section 621 and a stack negative control section 622. The characteristics of the stack positive control section 621 can be substantially the same as the characteristics of the transfer positive output section 631. The characteristics of the stack negative control section 622 can be substantially the same as the characteristics of the transfer negative output section 632. A third hole area HA3 can be located between the stack positive control section 621 and the stack negative control section 622.

The stack control section 620 can form an electric field in the third hole area HA3. For example, the stack positive control section 621 can be an electrode to which a positive voltage is applied. The stack negative control section 622 can be an electrode to which a negative voltage is applied. When a positive voltage is supplied to the stack positive control section 621 and a negative voltage is supplied to the stack negative control section 622, an electric field can be formed between the stack positive control section 621 and the stack negative control section 622.

The stack control section 620 can form an electric field in the third hole area HA3. For example, the stack positive control section 621 can be a silicon layer doped negatively. The stack positive control section 621 can be silicon to which phosphorus, arsenic, and/or the like corresponding to group 5 are added. The stack negative control section 622 can be a silicon layer doped positively. The stack negative control section 622 can be silicon to which boron, aluminum, and/or the like corresponding to group 3 are added. When a positive voltage is supplied to the stack positive control section 621 and a negative voltage is supplied to the stack negative control section 622, an electric field can be formed between the stack positive control section 621 and the stack negative control section 622.

The light emitting element stack section 623 can be disposed on the stack control section 620. The light emitting element stack section 623 can be in an electrically neutral state. The light emitting element stack section 623 can include an organic material. For example, the light emitting element stack section 623 can include a silicon material. The light emitting element stack section 623 can be a layer in which a plurality of light emitting elements ED are stacked. When viewed based on the cross-sectional view illustrated in FIG. 6, a second hole area HA2 can be located between a left portion of the light emitting element stack section 623 and a right portion of the light emitting element stack section 623. A plurality of light emitting elements ED can be located in the second hole area HA2.

The injection part 310 can be placed on the light emitting element stack section 623. The injection part 310 can include a positive injection section 611 and a negative injection section 612. The characteristics of the positive injection section 611 can be substantially the same as the characteristics of the transfer positive output section 631. The characteristics of the negative injection section 612 can be substantially the same as the characteristics of the transfer negative output section 632. A first hole area HA1 can be located between the positive injection section 611 and the negative injection section 612.

The injection part 310 can form an electric field in the first hole area HA1. For example, the positive injection section 611 can be an electrode to which a positive voltage is applied. The negative injection section 612 can be an electrode to which a negative voltage is applied. When a positive voltage is supplied to the positive injection section 611 and a negative voltage is supplied to the negative injection section 612, an electric field can be formed between the positive injection section 611 and the negative injection section 612.

The injection part 310 can form an electric field in the first hole area HA1. For example, the positive injection section 611 can be a silicon layer doped negatively. The positive injection section 611 can be silicon to which phosphorus, arsenic, and/or the like corresponding to group 5 are added. The negative injection section 612 can be a silicon layer doped positively. The negative injection section 612 can be silicon to which boron, aluminum, and/or the like corresponding to group 3 are added. When a positive voltage is supplied to the positive injection section 611 and a negative voltage is supplied to the negative injection section 612, an electric field can be formed between the positive injection section 611 and the negative injection section 612.

The diameter D2 of an upper portion of the first hole area HA1 can be greater than the diameter D1 of a lower portion of the first hole area HA1. In the first direction D1, a portion of the first hole area HA1 can have a shape in which the diameter of the first hole area HA1 is gradually reduced from top to bottom. For example, a half (e.g., an upper portion) of the first hole area HA1 can have an inverted cone shape, and the other half (e.g., a lower portion) thereof can have a cylindrical shape. Due to the shape of the first hole area HA1, light emitting elements ED can be more easily injected into the first hole area HA1.

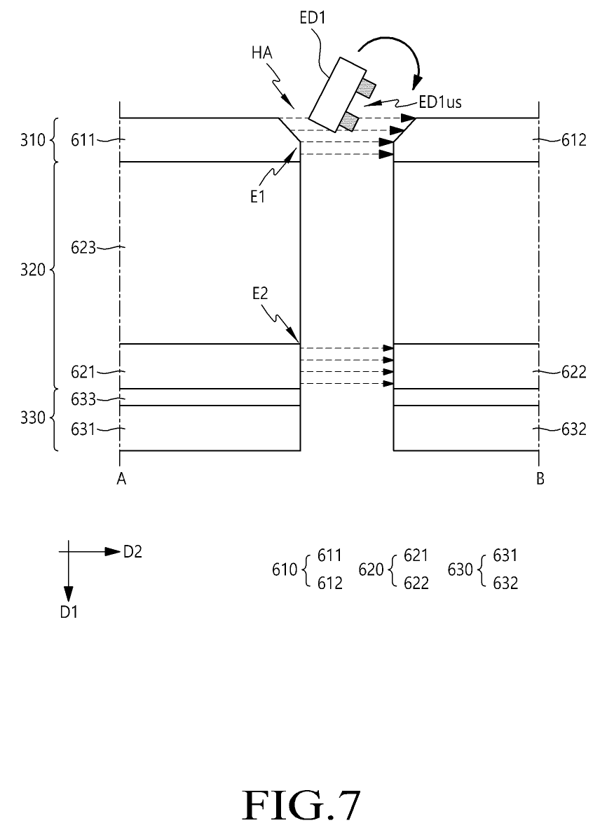

Referring to FIG. 7, an electric field can be formed between the positive injection section 611 and the negative injection section 612. The electric force lines of the electric field can be directed from the positive injection section 611 to the negative injection section 612.

At least one first light emitting element ED1 can be moved to the first hole area HA1. In one or more aspects, the first light emitting element ED1 can be inserted into the light emitting element transfer apparatus 300 by an inkjet method, a dropper method, or the like. In one or more aspects, a solution containing a plurality of light emitting elements ED can be injected into the light emitting element transfer apparatus 300. For example, the solution can be ethylene glycol, or the like.

The first light emitting element ED1 can include an emission layer, a first electrode, and a second electrode. The emission layer can emit light, and the first electrode and the second electrode can be disposed on a side of the emission layer. The emission layer can include an upper surface and a lower surface. A portion of the emission layer in which the first electrode and the second electrode are disposed can be the lower surface of the emission layer, and the opposite side thereof can be the upper surface.

When the first light emitting element ED1 is moved close to the first hole area HA1, the first electric field can electrically affect the first electrode and the second electrode. Accordingly, the first electrode and the second electrode can be located closer to the first electric field than the emission layer. In a situation where the first electrode and the second electrode are located closer to the first electric field than the emission layer, the first light emitting element ED1 can move into the first hole area HA1.

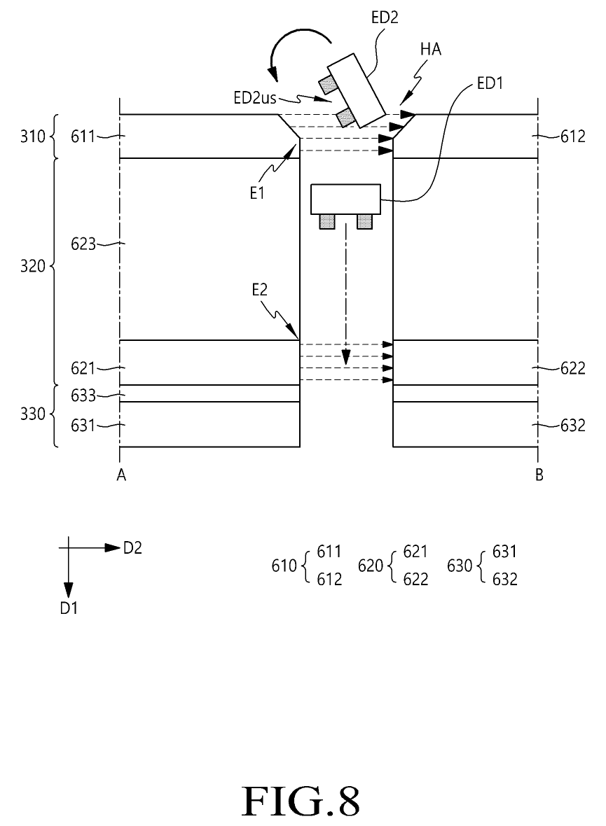

Thereafter, referring to FIG. 8, the first light emitting element ED1 can enter into the second hole area HA2. When the lower surface ED1us of the first light emitting element ED1 located in the first hole area HA1 faces downward in the first direction D1, the first electric field formed in the injection part 310 can be removed. Accordingly, the first light emitting element ED1 can move from the first hole area HA1 to the second hole area HA2.

For example, the first electrode and the second electrode of the first light emitting element ED1 can face downward in the first direction D1. In this example, the lower surface ED1us of the first light emitting element ED1 can face downward in the first direction D1. The first light emitting element ED1 can be located in the second hole area HA2. This can be expressed as the first light emitting element ED1 being stacked in the light emitting element stack section 623.

At least one second light emitting element ED2 can be moved to the first hole area HA1. When the second light emitting element ED2 is moved close to the first hole area HA1, the first electric field can affect the second light emitting element ED2. Accordingly, a lower surface ED2us of the second light emitting element ED2 can face downward in the first direction D1. Referring to FIG. 7, the lower surface ED1us of the first light emitting element ED1 can be tilted to the right, and therefore, the first light emitting element ED1 can rotate to the right. Referring to FIG. 8, the lower surface ED2us of the second light emitting element ED2 can be tilted to the left, and therefore, the second light emitting element ED2 can rotate to the left.

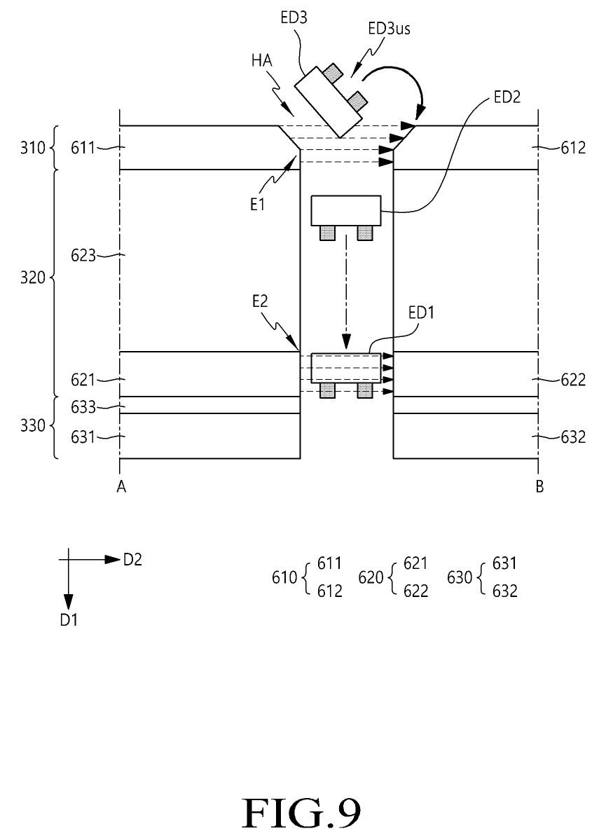

Referring to FIG. 9, the second light emitting element ED2 can pass through the first hole area HA1 and enter the second hole area HA2. In this situation, the first light emitting element ED1 can be located in the stack control section 620.

A second electric field E2 can be formed between the stack positive control section 621 and the stack negative control section 622. The electric force lines of the second electric field can be from the stack positive control section 621 to the stack negative control section 622. The second electric field can electrically affect the lower surface ED1us of the first light emitting element ED1, and therefore, the first light emitting element ED1 can be held in the stack control section 620.

A third light emitting element ED3 can be moved toward the injection part 310. In this situation, the first light emitting element ED1 can be located in the stack control section 620, the second light emitting element ED2 can be located in the light emitting element stack section 623, and the third light emitting element ED3 can be located close to the injection part 310. The third light emitting element ED3 can be rotated so that a lower surface ED3us faces downward by the first electric field E1.

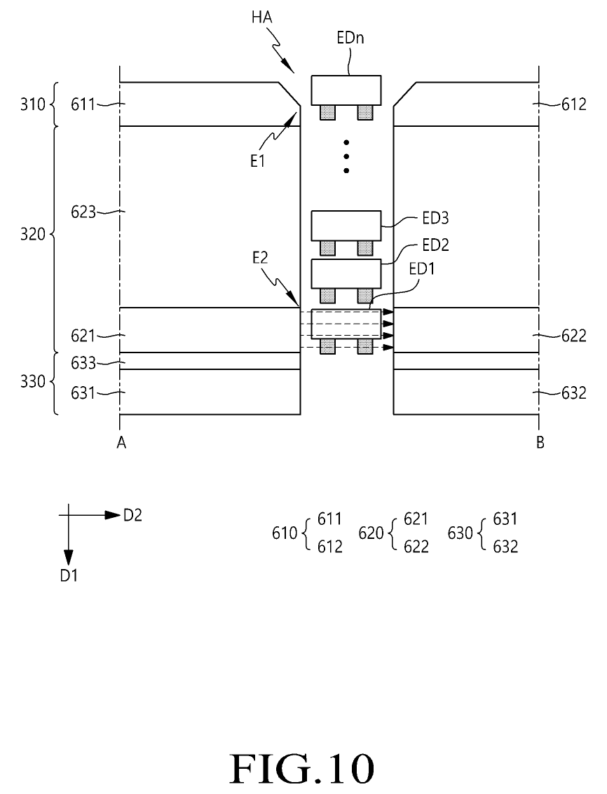

Referring to FIG. 10, the third light emitting element ED3 can pass through the first hole area HA1 and move to the second hole area HA2. Referring to FIG. 10, the first light emitting element ED1 can be located in the stack control section 620, and the second light emitting element ED2 and the third light emitting element ED3 can be located in the light emitting element stack section 623. The above-described processes can be repeated, and an n^{th} light emitting element EDn can be located in the injection part 310.

Through the second electric field formed in the stack control section 620, light emitting elements ED can be sequentially stacked in the light emitting element stack section 623.

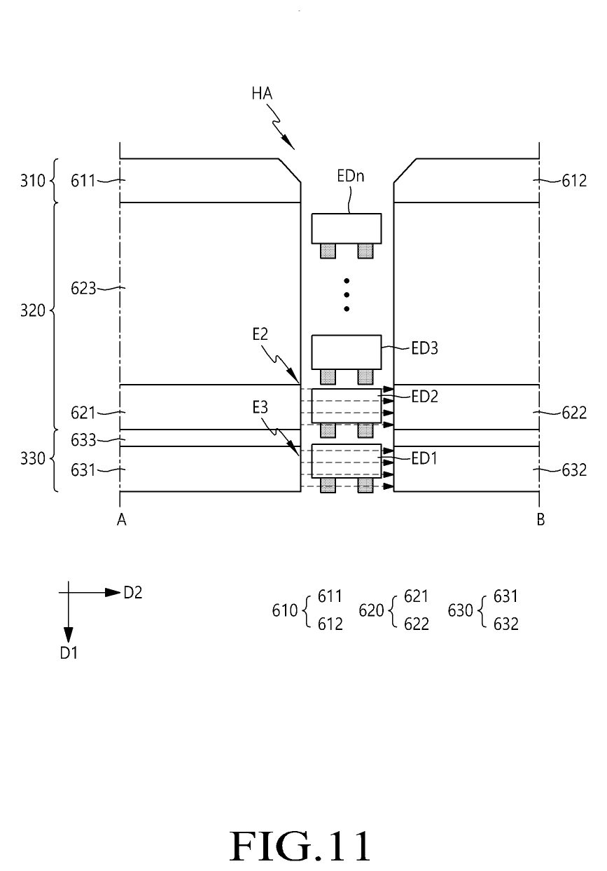

Referring to FIG. 11, in a situation where the second electric field of the stack control section 620 is formed, a third electric field E3 can be formed in the transfer output section 630. The electric force lines of the third electric field of the transfer output section 630 can be directed from the transfer positive output section 630631 to the transfer negative output section 630632. Referring to FIG. 11, when the second electric field is removed from the stack control section 620 and the third electric field is formed in the transfer output section 630, the first light emitting element ED1 can be located in the transfer output section 630. In this situation, the second light emitting element ED2 can be located in the stack control section 620, and the third light emitting element ED3 to the n^{th} light emitting element EDn can be located in the light emitting element stack section 623.

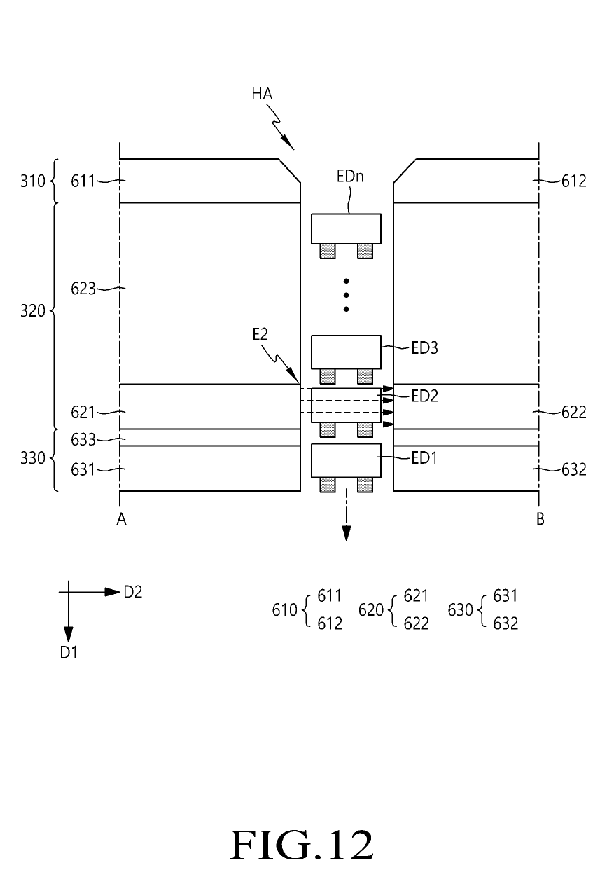

Referring to FIG. 12, the third electric field of the transfer output section 630 can be removed, and as the third electric field is removed, the first light emitting element ED1 can move downward in the first direction D1. Even when the first light emitting element ED1 moves downward from the transfer output section 630, the second light emitting element ED2 can be located in the stack control section 620. For example, even when the first light emitting element ED1 located in the transfer output section 630 moves under from the transfer output section 630, the second light emitting element ED2 can be still held in the stack control section 620.

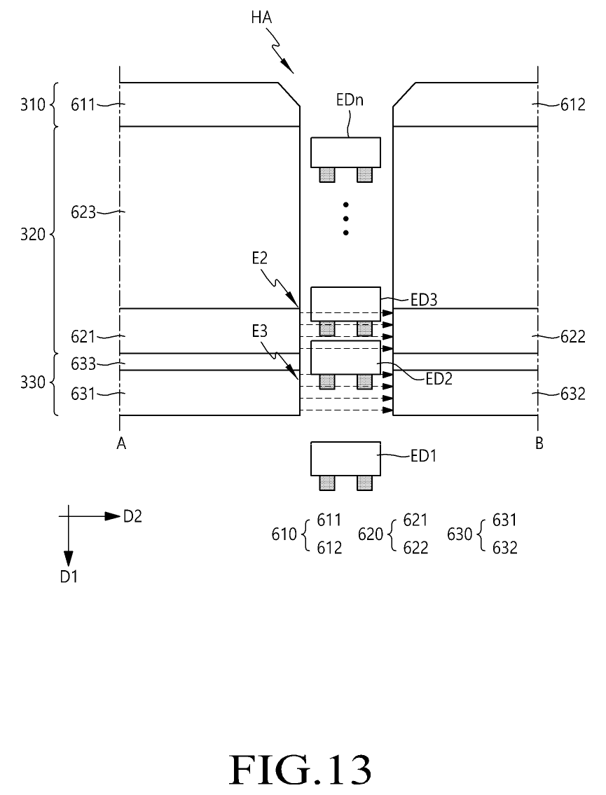

Referring to FIG. 13, the third electric field can be formed again in the transfer output section 630, and thereafter, the second electric field of the stack control section 620 can be removed for a while. Thereby, the second light emitting element ED2 can be located in the transfer output section 630, and the third light emitting element ED3 can be located in the stack control section 620.

Referring to FIGS. 6 to 13, it has been described that the locations of a plurality of light emitting elements ED can be controlled by the light emitting element transfer apparatus 300. Hereinafter, examples in which light emitting elements ED are transferred from the light emitting element transfer apparatus 300 onto the substrate 111 will be described.

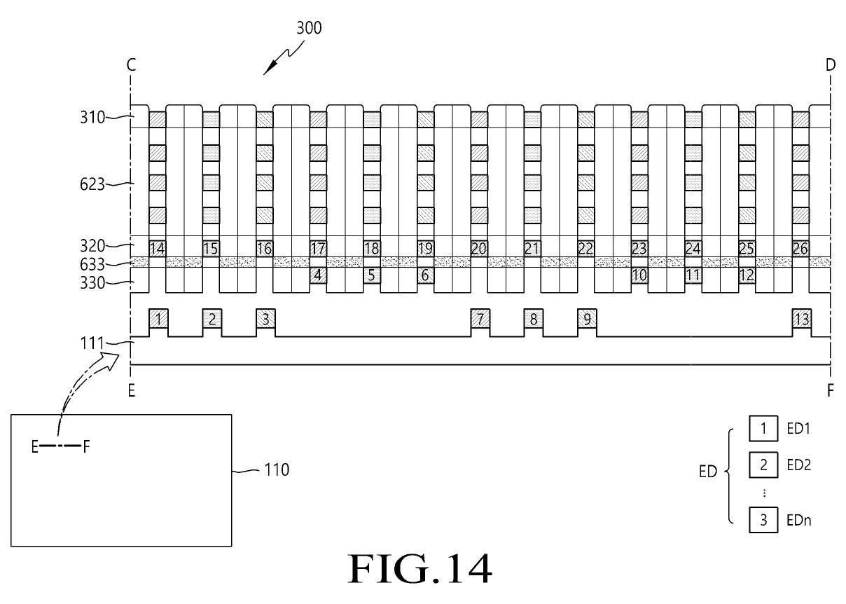

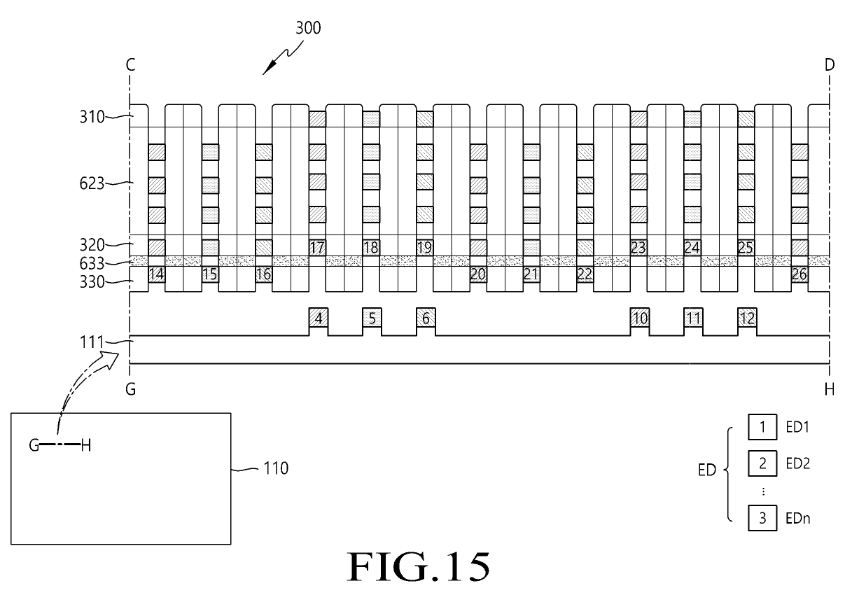

FIGS. 14 and 15 illustrate example transferring of light emitting elements ED onto the substrate 111 in the light emitting element transfer apparatus 300 according to aspects of the present disclosure.

Particularly, FIG. 14 illustrates a cross-sectional view of area C-D in the light emitting element transfer apparatus 300 illustrated in FIG. 5. Further, FIG. 14 illustrates a portion of the substrate 111 in area E-F of the display panel 110.

Referring to FIG. 14, first to thirteenth light emitting elements (ED1 to ED13) can be located in the transfer output section 630, and fourteenth to twenty-sixth light emitting elements (ED14 to ED26) can be located in the stack control section 620. Referring to FIG. 14, respective numbers of the light emitting elements ED is written on the light emitting elements ED.

Electric field can be removed from some of a plurality of transfer output sections 630, and thereby, the first to third light emitting elements (ED1 to ED3), the seventh to ninth light emitting elements (ED7 to ED9), and the thirteenth light emitting element ED13 can be transferred onto the substrate 111. In this situation, for an appropriate spacing between pixels, the fourth to sixth light emitting elements (ED4 to ED6) and the tenth to twelfth light emitting elements (ED10 to ED12) may not be transferred onto the substrate 111.

FIG. 15 illustrates a portion of the substrate 111 in area G-H of the display panel 110. Referring to FIG. 15, the fourth to sixth light emitting elements (ED4 to ED6) and the tenth to twelfth light emitting elements (ED10 to ED12) can be transferred onto the substrate 111.

Thereafter, the fourteenth to sixteenth light emitting elements (ED14 to ED16) and the twentieth to twenty-second light emitting elements (ED20 to ED22), and the twenty-sixth light emitting element ED26 can be located in the transfer output section 630. Further, the seventeenth to nineteenth light emitting elements (ED17 to ED19) and the twenty-third to twenty-fifth light emitting elements (ED23 to ED25) can be located in the stack control section 620.

The foregoing discussions can be summarized as follows. A control device (e.g., the light emitting element transfer apparatus 300) can transfer light emitting elements ED onto the substrate 111. A plurality of light emitting elements ED can be stacked in the control device. Light emitting elements ED can be injected into the control device through the injection part 310, and the locations of the light emitting elements ED can be aligned through the injection part 310. The plurality of light emitting elements ED can be stacked in the light emitting element stack section 623. Further, one light emitting element ED can be located in the stack control section 620, and the light emitting elements ED located in the light emitting element stack section 623 can be located inside of the control device through the light emitting element ED located in the stack control section 620. In a situation where the light emitting element ED is located in the stack control section 620, as electric field is removed in the stack control section 620, the light emitting element ED can be transferred onto the substrate 111.

The injection part 310 of the control device can easily align and stack a plurality of light emitting elements ED so that the lower surfaces of the light emitting elements ED face downward in the first direction D1. Accordingly, the light emitting elements ED can be easily stacked inside of the light emitting element transfer apparatus 300.

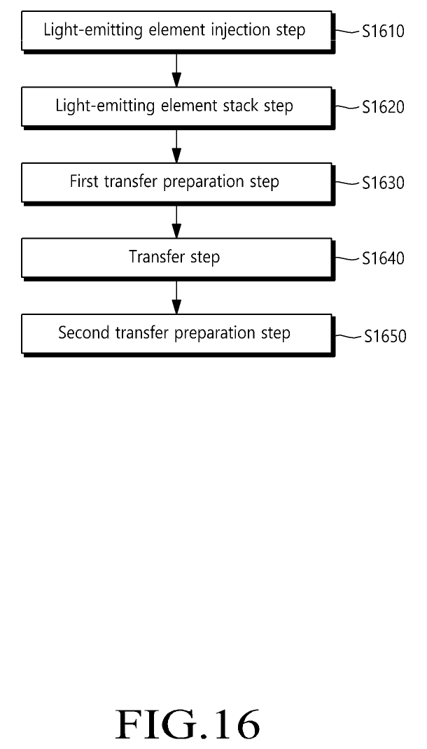

FIG. 16 is a flowchart of a method of driving a light emitting element transfer apparatus according to aspects of the present disclosure.

Referring to FIG. 16, in a light emitting element injection step S1610, the first electric field E1 is formed by the element injection part 310 to hold the first light emitting element ED1 among the plurality of light emitting elements ED in the element injection part 310. The lower portion of the first light emitting element ED1 faces a specific direction by the first electric field E1.

In a light emitting element stacking step S1620, the second electric field E2 is formed by the stack part 320 located under the element injection part and the first electric field E1 is removed by the element injection part 310 such that the first light emitting element ED1 moves into the stack part 320 and is held therein. The plurality of light emitting elements ED are stacked in the stack part 320.

In a first transfer preparation step S1630, the third electric field E3 is formed by the output part 330 located under the element injection part 310 and the second electric filed E2 is removed by the stack part 320 such that the first light emitting element ED1 moves into the output part 330 and is held therein. The second light emitting element ED2 among the plurality of light emitting elements ED is located in the stack part 320 by the second electric field E2 formed again.

In a transfer step S1640, the third electric field E3 is removed by the output part 330 such that the first light emitting element ED1 is transferred onto a substrate.

In a second transfer preparation step S1650, the second light emitting element ED2 is located in the output part 330 by the third electric field E3 formed again, and the third light emitting element ED3 among the plurality of light emitting elements ED is located in the stack part 320 by the second electric field E2 formed again.

The examples, aspects, and embodiments for the light emitting element transfer apparatus 300 described herein can be described as follows.

According to the one or more example embodiments described herein, a light emitting element transfer apparatus can include a plurality of injection parts into which a plurality of light emitting elements are respectively injected, a plurality of stack parts corresponding respectively to the plurality of injection parts and allowing the plurality of light emitting elements respectively injected into the plurality of injection parts to be stacked, and a plurality of output parts corresponding respectively to the plurality of stack parts and outputting sequentially the plurality of light emitting elements stacked in the plurality of stack parts.

In one or more aspects, each of the plurality of injection parts can include a positive injection section, a negative injection section, and an element injection section including a first hole area located between the positive injection section and the negative injection section. In one or more aspects, each of the plurality of stack parts can include a light emitting element stack section disposed under the element injection section and including a second hole area located under the first hole area, and a stack control section including a stack positive control section, a stack negative control section, and a third hole area located between the stack positive control section and the stack negative control section. In one or more aspects, each of the plurality of output parts can include an insulation section located under the stack control section, including a fourth hole area located under the third hole area, and including an insulating material, and a transfer output section including a transfer positive output section, a transfer negative output section, and a fifth hole area located between the transfer positive output section and the transfer negative output section.

In one or more aspects, each of the plurality of injection parts can enable a first electric field to form between the positive injection section and the negative injection section. In one or more aspects, the stack control section can enable a second electric field to form between the stack positive control section and the stack negative control section. In one or more aspects, the transfer output section can enable a third electric field to form between the transfer positive output section and the transfer negative output section.

In one or more aspects, each of the plurality of injection parts can form the first electric field to enable at least one first light emitting element among the plurality of light emitting elements to rotate, and enable a lower portion of the first light emitting element to face a first direction. For example, the first direction can be a direction from the first hole area to the second hole area.

In one or more aspects, each of the plurality of injection parts removes the first electric field after the lower portion of the first light emitting element is placed to face the first direction, such that the first light emitting element can be located in the second hole area of the light emitting element stack section.

In one or more aspects, when the first light emitting element is located in the second hole area, at least one second light emitting element among the plurality of light emitting elements can be located in the first hole area of the element injection section.

In one or more aspects, the stack control section forms the second electric field to hold the first light emitting element in the third hole area when the first light emitting element moves to the third hole area from the second hole area.

In one or more aspects, the second light emitting element can be located on the first light emitting element located in the third hole area, and the second light emitting element and the third light emitting element among the plurality of light emitting elements can be located in the second hole area of the light emitting element stack section.

In one or more aspects, the transfer output section can form the third electric field, and after the transfer output section has formed the third electric field, the stack control section can remove the second electric field.

In one or more aspects, the first light emitting element can be located in the fifth hole area by the third electric field, and the second light emitting element can be located in the third hole area by the second electric field formed again by the stack control section.

In one or more aspects, the transfer output section can remove the third electric field such that the first light emitting element is transferred onto a substrate in the first direction from the transfer output section, and when the third electric field is removed by the transfer output section, the stack control section can maintain the second electric field, such that the second light emitting element is held in the third hole area.

In one or more aspects, the transfer output section can form the third electric field again, and the stack control section removes the second electric field again, such that the second light emitting element can be located in the fifth hole area of the transfer output section.

In one or more aspects, the positive injection section can be an electrode to which a first voltage is applied, and the negative injection section can be an electrode to which a second voltage less than the first voltage is applied.

In one or more aspects, the positive injection section can include a silicon material doped with a first type, and the negative injection section can include a silicon material doped with a second type different from the first type. In one or more aspects, when the first voltage is supplied to the positive injection section and the second voltage having a lower voltage level than the first voltage is supplied to the negative injection section, the element injection section can form the first electric field in the first hole area.

In one or more aspects, a diameter of an upper portion of the first hole area can be greater than a diameter of a lower portion of the first hole area, and the diameter of the upper portion is gradually reduced from top to bottom.

According to the one or more example embodiments described herein, a method of driving a light emitting element transfer apparatus can include a light emitting element injection step of forming a first electric field by an element injection part to hold a first light emitting element among a plurality of light emitting elements in the element injection part, a light emitting element stacking step of forming a second electric field by an stack part located under the element injection part and removing the first electric field by the element injection part such that the first light emitting element moves into the stack part and is held therein, a first transfer preparation step of forming a third electric field by an output part located under the element injection part and removing the second electric field by the stack part such that the first light emitting element moves into the output part and is held therein, and a transfer step of removing the third electric field by the output part such that the first light emitting element is transferred onto a substrate.

In one or more aspects, in the light emitting element injection step, a lower portion of the first light emitting element can be caused to face a specific direction by the first electric field.

In one or more aspects, in the light emitting element stacking step, the plurality of light emitting elements can be stacked in the stack part.

In one or more aspects, in first transfer preparation step, at least one second light emitting element among the plurality of light emitting elements can be located in the stack part by the second electric field formed again.

In one or more aspects, the method further including a second transfer preparation step performed after the transfer step, and in the second transfer preparation step, the second light emitting element can be located in the output part by the third electric field formed again, and at least one third light emitting element among the plurality of light emitting elements can be located in the stack part by the second electric field formed again.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein can be applied to other embodiments and applications without departing from the scope of the present invention. The above description and the accompanying drawings provide examples of the technical features of the present invention for illustrative purposes only. For example, the disclosed embodiments are intended to illustrate the scope of the technical features of the present invention.

What is claimed is:

1. A light emitting element transfer apparatus comprising:
a plurality of injection parts into which a plurality of light emitting elements are respectively injected,
a plurality of stack parts corresponding respectively to the plurality of injection parts and allowing the plurality of light emitting elements respectively injected into the plurality of injection parts to be stacked; and
a plurality of output parts corresponding respectively to the plurality of stack parts and outputting sequentially the plurality of light emitting elements stacked in the plurality of stack parts.

2. The light emitting element transfer apparatus of claim 1, wherein each of the plurality of injection parts comprises a positive injection section, a negative injection section, and an element injection section, the element injection section comprising a first hole area located between the positive injection section and the negative injection section,
wherein each of the plurality of stack parts comprises:
a light emitting element stack section disposed under the element injection section and comprising a second hole area located under the first hole area; and
a stack control section comprising a stack positive control section, a stack negative control section, and a third hole area located between the stack positive control section and the stack negative control section, and
wherein each of the plurality of output parts comprises:
an insulation section located under the stack control section, and comprising a fourth hole area located under the third hole area, the insulation section including an insulating material; and
a transfer output section comprising a transfer positive output section, a transfer negative output section, and a fifth hole area located between the transfer positive output section and the transfer negative output section.

3. The light emitting element transfer apparatus of claim 2, wherein each of the plurality of injection parts enables a first electric field to form between the positive injection section and the negative injection section,
wherein the stack control section enables a second electric field to form between the stack positive control section and the stack negative control section, and
wherein the transfer output section enables a third electric field to form between the transfer positive output section and the transfer negative output section.

4. The light emitting element transfer apparatus of claim 3, wherein each of the plurality of injection parts forms the first electric field to enable a first light emitting element among the plurality of light emitting elements to rotate,
wherein the first electric field enables a lower portion of the first light emitting element to face a first direction, and
wherein the first direction is a direction extending from the first hole area to the second hole area.

5. The light emitting element transfer apparatus of claim 4, wherein each of the plurality of injection parts removes the first electric field after the lower portion of the first light emitting element is placed to face the first direction, so that the first light emitting element moves into the second hole area of the light emitting element stack section.

6. The light emitting element transfer apparatus of claim 5, wherein, when the first light emitting element is located in the second hole area, a second light emitting element among the plurality of light emitting elements is located in the first hole area of the element injection section.

7. The light emitting element transfer apparatus of claim 6, wherein the stack control section forms the second electric field to hold the first light emitting element in the third hole area when the first light emitting element moves to the third hole area from the second hole area.

8. The light emitting element transfer apparatus of claim 7, wherein the second light emitting element is located on the first light emitting element located in the third hole area, and the second light emitting element and a third light emitting element among the plurality of light emitting elements are located in the second hole area of the light emitting element stack section.

9. The light emitting element transfer apparatus of claim 8, wherein the transfer output section forms the third electric field, and after the transfer output section has formed the third electric field, the stack control section removes the second electric field.

10. The light emitting element transfer apparatus of claim 9, wherein the first light emitting element is located in the fifth hole area by the third electric field, and
wherein the second light emitting element is located in the third hole area by the second electric field formed again by the stack control section.

11. The light emitting element transfer apparatus of claim 10, wherein the transfer output section removes the third electric field, so that the first light emitting element is transferred onto a substrate in the first direction from the transfer output section, and
wherein, when the third electric field is removed by the transfer output section, the stack control section maintains the second electric field, so that the second light emitting element is held in the third hole area.

12. The light emitting element transfer apparatus of claim 11, wherein the transfer output section forms the third electric field again, and the stack control section removes the second electric field again, so that the second light emitting element is located in the fifth hole area of the transfer output section.

13. The light emitting element transfer apparatus of claim 2, wherein the positive injection section is an electrode to which a first voltage is applied, and the negative injection section is an electrode to which a second voltage less than the first voltage is applied.

14. The light emitting element transfer apparatus of claim 2, wherein the positive injection section comprises a silicon material doped with a first type doping, and the negative injection section comprises a silicon material doped with a second type doping different from the first type doping, and
wherein when a first voltage is supplied to the positive injection section and a second voltage having a lower voltage level than the first voltage is supplied to the negative injection section, the element injection section forms a first electric field in the first hole area.

15. The light emitting element transfer apparatus of claim 2, wherein a diameter of an upper portion of the first hole area is greater than a diameter of a lower portion of the first hole area, and the diameter of the upper portion is gradually reduced from a top to a bottom of the upper portion of the first hole.

16. A method of driving a light emitting element transfer apparatus, the method comprising:
a light emitting element injection step of forming a first electric field by an element injection part to hold a first light emitting element among a plurality of light emitting elements in the element injection part;
a light emitting element stacking step of forming a second electric field by an stack part located under the element injection part and removing the first electric field by the element injection part so that the first light emitting element moves into the stack part and is held therein;
a first transfer preparation step of forming a third electric field by an output part located under the element injection part and removing the second electric field by the stack part so that the first light emitting element moves into the output part and is held therein; and
a transfer step of removing the third electric field by the output part so that the first light emitting element is transferred onto a substrate.

17. The method of claim 16, wherein in the light emitting element injection step, a lower portion of the first light emitting element is configured to face a specific direction by the first electric field.

18. The method of claim 16, wherein in the light emitting element stacking step, the plurality of light emitting elements are stacked in the stack part.

19. The method of claim 16, wherein in the first transfer preparation step, a second light emitting element among the plurality of light emitting elements is located in the stack part by the second electric field formed again.

20. The method of claim 19, further comprising a second transfer preparation step performed after the transfer step,
wherein in the second transfer preparation step, the second light emitting element is located in the output part by the third electric field formed again, and a third light emitting element among the plurality of light emitting elements is located in the stack part by the second electric field formed again.
